(19) United States
(12) Patent Application Publication
(10) Pub. No.: US 2025/0351390 A1
(43) Pub. Date: Nov. 13, 2025

(54) CAPACITOR STRUCTURE AND METHOD FOR FABRICATING THE CAPACITOR

(71) Applicant: Taiwan Semiconductor Manufacturing Company, Ltd., Hsinchu (TW)

(72) Inventors: Hsin-Yu LAI, Hsinchu (TW); Pei-Yun Wang, Hsinchu City (TW); Katherine H. CHIANG, New Taipei City (TW)

(73) Assignee: Taiwan Semiconductor Manufacturing Company, Ltd., Hsinchu (TW)

(21) Appl. No.: 18/659,025

(22) Filed: May 9, 2024

(51) Int. Cl. H10D 1/68; H10D 1/00

(52) U.S. Cl. CPC H10D 1/696; H10D 1/042; H10D 1/043; H10D 1/716

(57) ABSTRACT

A capacitor structure and a method for fabricating the capacitor are provided. The capacitor structure includes a first dielectric layer, a first conductive via embedded in the first dielectric layer, an etch stop layer disposed on the first dielectric layer, a second dielectric layer disposed on the etch stop layer, and a capacitor embedded in the first dielectric layer, the etch stop layer and the second dielectric layer. The capacitor is disposed on and electrically connected to the first conductive via. A contact interface between the first conductive via and the capacitor is lower than an interface between the first dielectric layer and the etch stop layer.

### BACKGROUND

Integrated chips are formed on semiconductor die including millions or billions of transistor devices. The transistor devices are configured to act as switches and/or to produce power gains so as to enable logical functionality for an integrated chip (e.g., form a processor configured to perform logic functions). Integrated chips also include passive devices, such as capacitors, resistors, inductors, varactors, etc. Therefore, the improved the capacitor and the improved process of fabricating the capacitors are desired as a development of a semiconductor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 8 illustrate the cross-sectional views of intermediate stages in the formation of a metal-insulator-metal (MIM) device in accordance with some embodiments.

FIG. 9 to FIG. 10C illustrate the cross-sectional views of intermediate stages in the formation of a MIM device in accordance with some embodiments.

FIG. 11 to FIG. 12E illustrate the cross-sectional views of intermediate stages in the formation of a MIM device in accordance with some embodiments.

FIG. 13 to FIG. 17 illustrate the cross-sectional views of intermediate stages in the formation of a MIM device in accordance with some embodiments.

FIG. 18A to FIG. 18E schematically illustrate the shapes of the first conductive vias and the capacitor when viewing from atop of the first conductive vias and the capacitor.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A capacitor structure and a method for fabricating the capacitor are provided. An oxide layer between a bottom electrode and the capacitor is removed in the fabrication method for forming the capacitor structure with low resistance, thereby increasing the capacitive coupling area of the capacitor structure and improving the quality of the capacitor structure. Accordingly, the electrical performance of the capacitor structure can be improved.

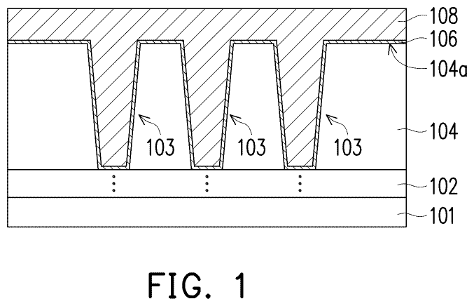

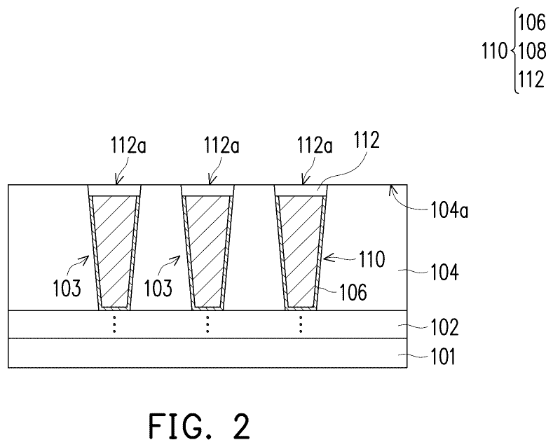

FIG. 1 to FIG. 8 illustrate the cross-sectional views of intermediate stages in the formation of a metal-insulator-metal (MIM) device in accordance with some embodiments.

Referring to FIG. 1, an interconnect structure includes lower insulating layers 102 having lower interconnect wirings and lower conductive vias (not shown), a first dielectric layer 104, and subsequently formed first conductive vias 110 (shown in FIG. 2). The interconnect structure is formed over a substrate 101 (e.g., a semiconductor substrate). The lower interconnect wirings and the lower conductive vias are alternatively stacked over the substrate 101 and are embedded in the lower insulating layers 102. The lower interconnect wirings and the lower conductive vias may be formed by, for example, CVD, PVD, ALD, sputtering, electrochemical plating, electroless plating, some other deposition process, or a combination of the foregoing. The lower insulating layers 102 and the first dielectric layer 104 may be formed by, for example, chemical vapor deposition (CVD), physical vapor deposition (PVD), atomic layer deposition (ALD), some other process, or a combination of the foregoing. While not shown in FIG. 1, it will be appreciated that one or more semiconductor devices (e.g., transistors, MOSFETs, etc.), may be formed in the substrate 101 by complementary metal-oxide-semiconductor (CMOS) processes.

Via holes 103 are formed within the first dielectric layer 104. The via holes 103 are formed to penetrate through the first dielectric layer 104 as well as reveal top surfaces of the interconnect wirings (not shown) within the lower insulating layers 102. The via holes 103 are formed in the first dielectric layer 104. The via holes 103 extend from top surfaces 104a of the first dielectric layer 104 to the top surfaces of interconnect wirings (not shown) within the lower insulating layers 102. The via holes 103 may be formed with substantially vertical sidewalls, not shown in figures. In some embodiments, as illustrated in FIG. 1, the via holes 103 are formed with inclined sidewalls.

A barrier layer 106 may be conformally deposited on the first dielectric layer 104 such that the barrier layer 106 distributed in the via holes 103 of the first dielectric layer 104 and covers top surfaces 104a of the first dielectric layer 104. The via holes 103 are lined with the barrier layer 106. The barrier layer 106 may be formed using a process such as chemical vapor deposition (CVD), physical vapor deposition (PVD), plasma enhanced CVD (PECVD), plasma enhanced physical vapor deposition (PEPVD), atomic layer deposition (ALD), combinations of these, or the like. The barrier layer 106 may comprise tantalum nitride, although other materials, such as tantalum, titanium, titanium nitride, combinations of these, and the like may alternatively be used.

A conductive material 108 is deposited on the barrier layer 106. The conductive material 108 is deposited with sufficient amount and/or thickness to fill the via holes 103. The top surface of the conductive material 108 may be substantial planar. In some embodiments, the conductive material 108 may be deposited by, for example, ALD, CVD, PVD, electrochemical plating, electroless plating, sputtering, some other deposition process, or a combination of the foregoing. The conductive material 108 may be conductive and may be or include tungsten (W), copper (Cu), titanium (Ti), titanium nitride (TiN), tantalum (Ta), tantalum nitride (TaN), aluminum (Al), aluminum titanium (AlTi), some other conductive material, or a combination of the foregoing. The number of the via holes 103 is merely described for illustration, and the present disclosure is not limited thereto.

Referring to FIG. 2, after the depositing the conductive material 108 into the via holes 103, a planarization process or a removal process such as a CMP process is performed to partially remove the barrier layer 106 and the conductive material 108 until the top surface of the first dielectric layer 104 is exposed, such that the first conductive vias 110 embedded in the first dielectric layer 104 are formed. As illustrated in FIG. 2, the first conductive vias 110 comprise the barrier layers 106, the conductive materials 108 surrounded by the barrier layer 106, and metal oxides 112 on the barrier layers 106 and conductive material 108s. The conductive materials 108 are spaced apart from the first dielectric layer 104 by the barrier layers 106. The first conductive vias 110 may have a circle shape, a square shape, a rectangular shape, a slit shape with rounded ends or the like when viewing from atop of the first conductive vias 110. In some embodiments, the above-mentioned square shape and the rectangular shape of the first conductive vias 110 includes fillet corners when viewing from atop of the first conductive vias 110.

After performing the planarization process of the conductive material 108, the metal oxides 112 generate above the barrier layers 106 and the conductive materials 108 by oxidation of the revealed portions of the barrier layers 106 and the conductive materials 108. The metal oxides 112 may be an oxide of the material of the barrier layers 106 and/or an oxide of the material of the conductive materials 108. In some embodiments, thicknesses of the metal oxides 112 are about 5 Å to 50 Å. In some embodiments, the first dielectric layer 104 is a homogenous dielectric layer. Here, the homogenous dielectric layer means that the dielectric layer having uniform composition and/or property throughout. The homogenous dielectric layer is referred as to a dielectric layer having no obvious layer interface therein. The number of the metal oxides 112 and the first conductive vias 110 are merely described for illustration, and the present disclosure is not limited thereto.

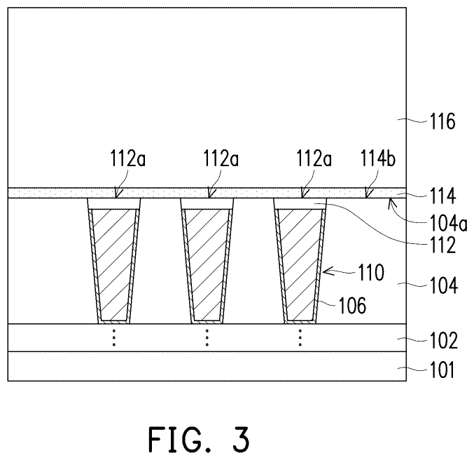

Referring to FIG. 3, an etch stop layer 114 is formed on the metal oxides 112 and the top surfaces 104a of the first dielectric layer 104, and a second dielectric layer 116 is formed on the etch stop layer 114. The first dielectric layer 104 and a second dielectric layer 116 may be formed by, for example, chemical vapor deposition (CVD), physical vapor deposition (PVD), atomic layer deposition (ALD), some other process, or a combination of the foregoing.

Top surfaces 112a of the metal oxides 112 of the first conductive vias 110 are substantially aligned with the top surfaces 104a of the first dielectric layer 104. The top surfaces 104a of the first dielectric layer 104 interface and are in contact with a bottom surface 114b of the etch stop layer 114.

In some embodiments, the etch stop layer 114 is a homogenous layer. In some embodiments, the etch stop layer 114 is homogenous. In some embodiments, the definition of “homogenous” is the material is identical wherever you sample it—it has uniform composition and properties throughout. In some embodiments, “homogenous” is without a phase interface. The number of the top surfaces 112a of the metal oxides 112 is merely described for illustration, and the present disclosure is not limited thereto.

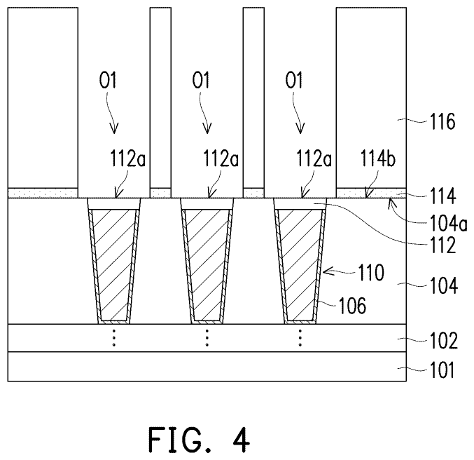

Referring to FIG. 4, the etch stop layer 114 and the second dielectric layer 116 are patterned by a photolithography process followed by an etch process, and a photomask is used in the photolithography process. In other words, a patterned photoresist layer (not shown) may be formed on the second dielectric layer 116 through the photolithography process, and then the second dielectric layer 116 and the etch stop layer 114 are partially removed through the etch process until the top surfaces 112a of the metal oxides 112 are revealed. Trenches O1 are formed to reveal the top surfaces 112a of the metal oxides 112 and sidewalls of the etch stop layer 114 and sidewalls of the second dielectric layer 116. The trenches O1 are formed in the etch stop layer 114 and the second dielectric layer 116. The number of the trenches O1 is merely described for illustration, and the present disclosure is not limited thereto.

In some embodiments, the etching process may be performed by exposing the second dielectric layer 116 to a first etchant. The first etchant may include a dry etchant (e.g., a reactive ion etching (RIE) etchant, a plasma etchant, or the like). In some embodiments, the first etchant may have an etching chemistry including one or more tetrafluoromethane (CF₄), fluoroform (CHF₃), chlorine (Cl₂), nitrogen (N₂), argon (Ar), boron trichloride (BCl₃), or the like. In some embodiments, wet clean process is preformed to remove by-products derived from the etching process. In some embodiments, after performing the removal process, any residual photoresist is removed by an ash process or by dissolution with a solvent. In some embodiments, the etching process may be an anisotropic etching process. The top surfaces 112a of the metal oxides 112 of the first conductive vias 110 are substantially aligned with the top surfaces 104a of the first dielectric layer 104 and a bottom surface 114b of the etch stop layer 114.

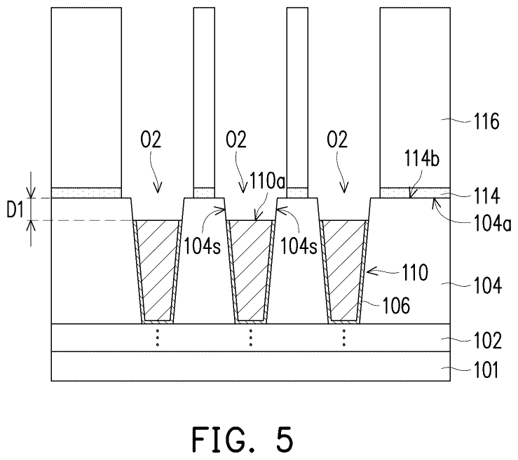

Referring to FIG. 5, the metal oxides 112 are then removed by a wet etching process to form the recesses O2. The recesses O2 reveal top surfaces 110a of the first conductive vias 110 and sidewalls 104s of the via holes 103 of the first dielectric layer 104. In some embodiments, the metal oxides 112 are removed after the recesses O2 is formed. In some embodiments, the first conductive vias 110 are partially removed until the recesses O2 are formed above the first conductive vias 110. The recesses O2 may be achieved through a wet etching process using an etchant that is more selective to the material of the metal oxides 112 than the material of the first dielectric layer 104. The wet etching process may be performed using an etchant such as HF. The wet etching process may be performed using a dip process, a spray process, a spin-on process, or the like, and may be performed using any suitable process temperatures. Depths D1 of the recesses O2 are defined by the top surfaces 110a of the first conductive vias 110 between the top surfaces 104a of the first dielectric layer 104 (or between the bottom surface 114b of the etch stop layer 114). The depths D1 of the recesses O2 is greater than about 10 Å.

In some embodiments, a surface treatment is performed to the top surfaces 110a of the conductive via 110. In some embodiments, performing the surface treatment includes a soaking process or a plasma treatment and a source gas used in the soaking process or the plasma treatment is N₂, H₂, O₂, Ar, NH₃, or a mixture thereof. The surface treatment may reduce an additional oxidation of the top surfaces 110a of the conductive via 110.

In some embodiments, a monolayer (not shown) is formed on the top surfaces 110a of the conductive via 110. The monolayer as like a protection layer prevents an additional oxidation on the top surfaces 110a of the conductive via 110 with the monolayer protection. In some embodiments, a plasma treatment is performed to remove the monolayer, and meanwhile revealed the top surfaces 110a of the conductive via 110 before forming capacitors 118. In some embodiments, the monolayer is derived from a monolayer precursor. In some embodiments, the monolayer precursor comprises alkanethiols, aromatic thiols, or the like. The number of the top surfaces 110a of the first conductive vias 110 is merely described for illustration, and the present disclosure is not limited thereto.

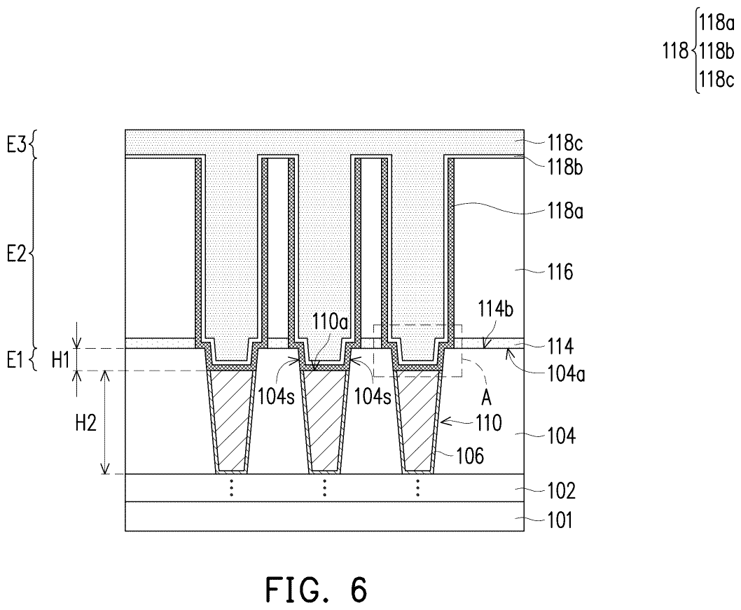

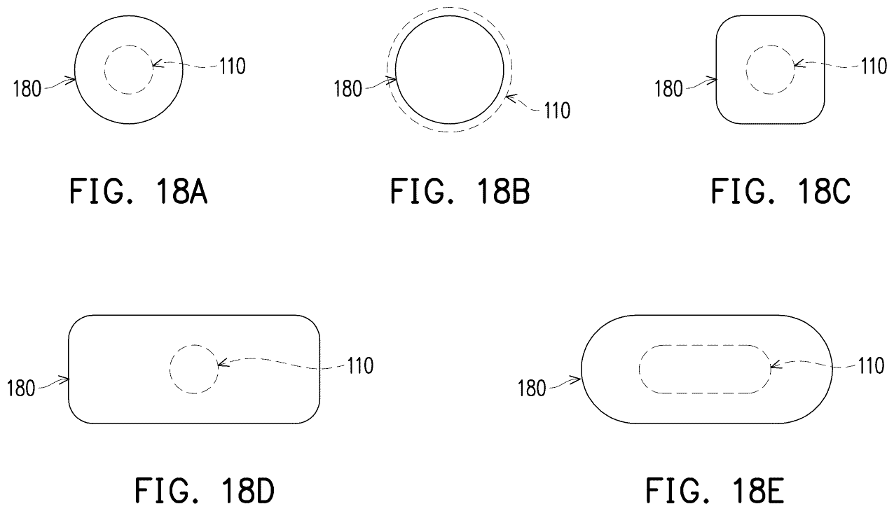

Referring to FIG. 6, the capacitors 118 are formed in the trenches O1 of the second dielectric layer 116 and the recesses O2. In some embodiments, a barrier layer (not shown) may be formed and lining the recesses O2, the trenches O1 and a top surface of the second dielectric layer 116, before forming the capacitors 118. The capacitors 118 are partially embedded in the first dielectric layer 104, the etch stop layer 114 and the second dielectric layer 116. In some embodiments, the capacitors 118 partially embedded in the first dielectric layer 104, the etch stop layer 114 and the second dielectric layer 116 may be a circle shape, a square shape, a rectangular shape, a slit shape with rounded ends or the like in a top view. In some embodiments, the above-mentioned square shape and the rectangular shape of the capacitors 118 includes fillet corners when viewing from atop of the capacitors 118. The shape of the capacitors 118 and the shape of the first conductive vias 110 are not limited. In some embodiments, the capacitors 118 and the first conductive vias 110 are similar in shape when viewing from atop of the capacitors 118 and the first conductive vias 110, as illustrated in FIGS. 18A and 18B. In FIG. 18A, both the capacitors 118 and the first conductive vias 110 have a circle shape when viewing from atop of the capacitors 118 and the first conductive vias 110, and the diameter of the circular-shaped capacitors 118 is greater than the diameter of the circular-shaped first conductive vias 110. In FIG. 18B, both the capacitors 118 and the first conductive vias 110 have a circle shape when viewing from atop of the capacitors 118 and the first conductive vias 110, and the diameter of the circular-shaped first conductive vias 110 is greater than the diameter of the circular-shaped capacitors 118. In some other embodiments, the capacitors 118 and the first conductive vias 110 are different in shape, as illustrated in FIGS. 18C to 18E when viewing from atop of the capacitors 118 and the first conductive vias 110. In FIG. 18C, the capacitors 118 has a square shape with fillet corners when viewing from atop of the capacitors 118, the first conductive vias 110 has a circle shape when viewing from atop of the first conductive vias 110, and the minimum width of the square-shaped capacitors 118 greater than the diameter of the circular-shaped first conductive vias 110. In FIG. 18D, the capacitors 118 has a rectangular shape with fillet corners when viewing from atop of the capacitors 118, the first conductive vias 110 has a circle shape when viewing from atop of the first conductive vias 110, and the minimum width of the rectangular-shaped capacitors 118 greater than the diameter of the circular-shaped first conductive vias 110. In FIG. 18E, the capacitors 118 has a slit shape with rounded ends when viewing from atop of the capacitors 118, the first conductive vias 110 has a slit shape with rounded ends when viewing from atop of the first conductive vias 110, and the dimension of the rectangular-shaped capacitors 118 greater than the dimension of the circular-shaped first conductive vias 110.

The capacitors 118 are disposed on and electrically connected to the first conductive vias 110. The capacitors 118 penetrate through the second dielectric layer 116 and protrudes into the first dielectric layer 104 to electrically connect the first conductive vias 110. Contact interfaces between the first conductive vias 110 and the capacitors 118 are lower than an interface between the first dielectric layer 104 and the etch stop layer 114. The top surfaces 110a of the first conductive vias 110 are lower than the top surfaces 104a of the first dielectric layer 104.

The capacitors 118 comprise first portions E1, second portions E2 and a third portion E3. The first portions E1 are embedded in the first dielectric layer 104. The second portion E2 land on the first portions E1 and are embedded in the etch stop layer 114 and the second dielectric layer 116. The third portion E3 lands on the second portions E2 and horizontally extends over the second dielectric layer 116. The first portions E1 of the capacitor 180 is spaced apart from the second dielectric layer 116 by the etch stop layer 114. The second portions E2 are physically in contact with the top surfaces 104a of the first dielectric layer 104. The second portions E2 land on the top surfaces 104a of the first dielectric layer 104.

Top ends of the barrier layers 106 are in contact with the first portions E1 of the capacitors 118. First level heights where the top ends of the barrier layers 106 are located is lower than a second level height wherein a bottom surface 114b of the etch stop layer 114 is located. Heights H1 of the first portions E1 are less than 90% of heights H2 of the conductive via 110.

The capacitors 118 include first capacitor electrode layers 118a disposed on and electrically connected to the first conductive vias 110; a capacitor dielectric layer 118b disposed on the first capacitor electrode layers 118a; and a second capacitor electrode layer 118c disposed on the capacitor dielectric layer 118b. The first capacitor electrode layers 118a, the capacitor dielectric layer 118b and the second capacitor electrode layer 118c are formed in a stack on the first conductive vias 110, line the via holes 103, and extend over the top surfaces 104a of the first dielectric layer 104. In some embodiments, a patterning process is performed to remove the horizontal extending portion of the first capacitor electrode layers 118a above the second dielectric layer 116.

In some embodiments, the first capacitor electrode layers 118a and the second capacitor electrode layer 118c may be deposited by, for example, ALD, CVD, PVD, electrochemical plating, electroless plating, sputtering, some other deposition process, or a combination of the foregoing. The first capacitor electrode layers 118a and the second capacitor electrode layer 118c may be conductive and may be or include Al, Ru, Ir, Os, Mo, Pt, Pd, some other conductive material, or a combination of the foregoing. In some embodiments, the first capacitor electrode layers 118a and the second capacitor electrode layer 118c are deposited with a thickness between approximately 10 angstroms (Å) and approximately 1000 Å.

The capacitor dielectric layer 118b is formed between the first capacitor electrode layers 118a and the second capacitor electrode layer 118c. The capacitor dielectric layer 118b may be or include AlₓO_{y} (e.g., Al₂O₃), ZrOₓ (e.g., ZrO₂), HfOₓ (e.g., HfO₂), HfZrOₓ (e.g., HfZrO₂), TiOₓ (e.g., TiO₂), HfTiOₓ (e.g., HfTiO), HfSiOₓ (e.g., HfSiO₄), HfLaOₓ (e.g., HfLaO), some other dielectric material, or any combination of the foregoing. The capacitor dielectric layer 118b may be deposited or grown by ALD, CVD, PVD, thermal oxidation, some other deposition or growth process, or a combination of the foregoing. In some embodiments, the capacitor dielectric layer 118b is formed with a thickness between about 10 Å and about 500 Å. In some embodiments, a number of the capacitor dielectric layer may be 1 or more, a number of the capacitor electrode layer may be 2 or more. The number of the dielectric layers and the number of the electrode layers are not limited thereto. The number of the trenches O1, the recesses O2, the capacitors 118, the first capacitor electrode layers 118a, the first portion E1 and the second portion E2 are merely described for illustration, and the present disclosure is not limited thereto.

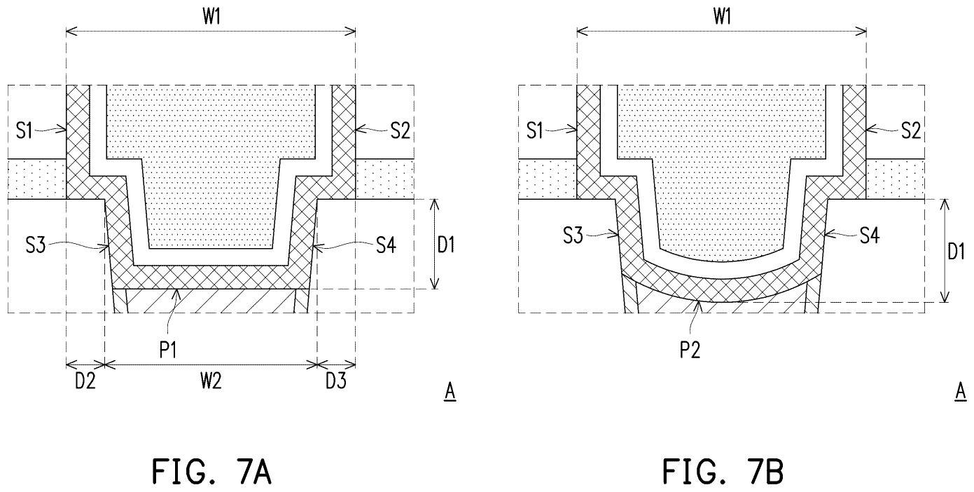

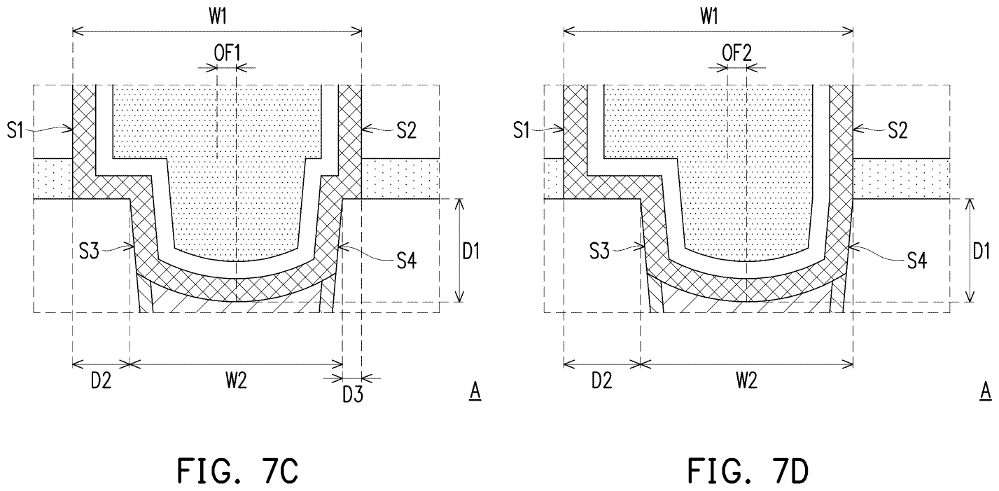

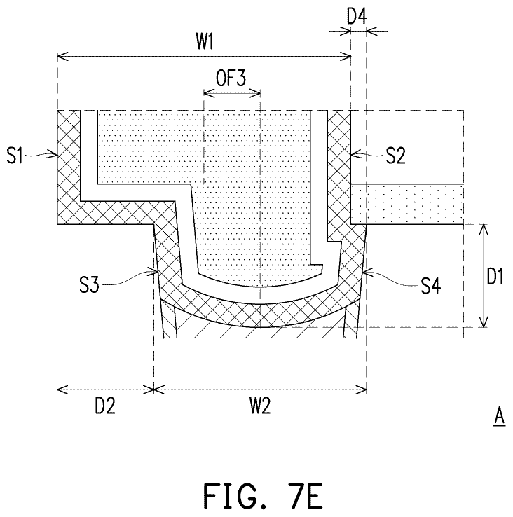

FIG. 7A is an enlarge view of a portion A of FIG. 6. Referring to FIG. 7A, the top surface 110a of the first conductive via 110 comprises a substantial planar surface P1. In some embodiments, a height of the first portion E1 of the capacitor 118 substantially equals to the depth D1 of the recess O2.

In some embodiments, a maximum width W2 of the first portion E1 is less than a minimum width W1 of the second portion E2, since a maximum width of the recess O2 is substantially less than a minimum width of the trench O1. In some embodiments, a first lateral offset D2 is between a first sidewall S1 of the second portion E2 of the capacitor 118 and a first sidewall S3 of the first portion E1 of the capacitor 118. In some embodiments, a second lateral offset D3 is between a second sidewall S2 of the second portion E2 of the capacitor 118 and a second sidewall S4 of the first portion E1 of the capacitor 118. In some embodiments, the first lateral offset D2 substantially equals to the second lateral offset D3. In some embodiments, a sum of the maximum width W2 of the first portion E1, the first lateral offset D2 and the second lateral offset D3 substantially equals to the minimum width W1 of the second portion E2.

Referring to FIG. 7B, the difference of FIG. 7B and FIG. 7A is that FIG. 7B shows the top surface 110a of the first conductive via 110 comprising a curved and concave surface P2.

Referring to FIG. 7C, unless further description as follows, the definition of the reference symbols and labeled representations are the same as FIG. 7B, and will not be repeated herein.

A first central line of the first portion E1 laterally offsets from a second central line of the second portion E2. An offset distance OF1 is defined by the first central line of the first portion E1 and the second central line of the second portion E2. In some embodiments, the first lateral offset D2 is different from the second lateral offset D3. In some embodiments, the first lateral offset D2 may be larger than or less than the second lateral offset D3. In some embodiments, an absolute value of half of difference of the first lateral offset D2 and the second lateral offset D3 substantially equals to the offset distance OF1.

Referring to FIG. 7D, unless further description as follows, the definition of the reference symbols and labeled representations are the same as FIG. 7C, and will not be repeated herein.

An offset distance OF2 is defined by the first central line of the first portion E1 and the second central line of the second portion E2. In some embodiments, the second sidewall S2 of the second portion E2 is continuous and levelled with the second sidewall S4 of the first portion E1. In some embodiments, half of the first lateral offset D2 substantially equals to the offset distance OF2. In some embodiments, a sum of the maximum width W2 of the first portion E1 and the first lateral offset D2 substantially equals to the minimum width W1 of the second portion E2. The offset distance OF2 is larger than the offset distance OF1.

Referring to FIG. 7E, unless further description as follows, the definition of the reference symbols and labeled representations are the same as FIG. 7C, and will not be repeated herein.

An offset distance OF3 is defined by the first central line of the first portion E1 and the second central line of the second portion E2. In some embodiments, a third lateral offset D4 is between the second sidewall S2 of the second portion E2 of the capacitor 118 and the second sidewall S4 of the first portion E1 of the capacitor 118. In some embodiments, the first lateral offset D2 is different from the third lateral offset D4. In some embodiments, the first lateral offset D2 may be larger than the third lateral offset D4. In some embodiments, half of sum of the first lateral offset D2 and the third lateral offset D4 substantially equals to the offset distance OF3. In some embodiments, a sum of the maximum width W2 of the first portion E1 and the first lateral offset D2 substantially equals to a sum of the minimum width W1 of the second portion E2 and the third lateral offset D4. The offset distance OF3 is larger than the offset distance OF2.

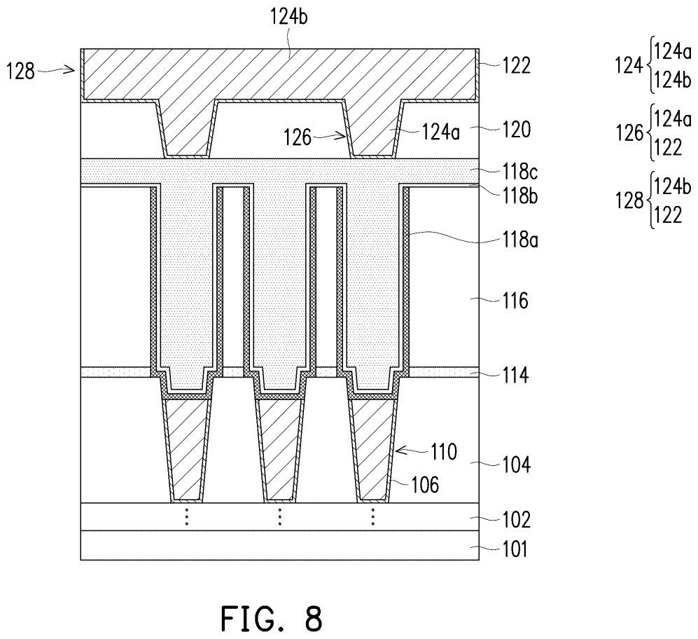

Referring to FIG. 8, forming second conductive vias 126 are formed on the capacitors 118. The second conductive vias 126 are disposed on and electrically connected to the second capacitor electrode layer 118c of the capacitors 118.

A third dielectric layer 120 is formed on the second capacitor electrode layer 118c of the capacitors 118. The third dielectric layer 120 may be formed by, for example, chemical vapor deposition (CVD), physical vapor deposition (PVD), atomic layer deposition (ALD), some other process, or a combination of the foregoing. Any suitable planarization process (such as Chemical-Mechanical Polishing (CMP)) may be performed on the third dielectric layer 120. In some embodiments, the third dielectric layer 120 may include silicon dioxide, silicon oxynitride, and/or the like.

The third dielectric layer 120 is patterned by a photolithography process followed by an etch process, and a photomask is used in the photolithography process. In other words, a patterned photoresist layer (not shown) may be formed on the third dielectric layer 120 through the photolithography process, and then the third dielectric layer 120 is partially removed through the etch process until the second capacitor electrode layer 118c of the capacitors 118 is revealed in openings.

A barrier layer 122 may be deposited in the openings of the third dielectric layer 120, deposited on the second capacitor electrode layer 118c of the capacitors 118, and deposited on the third dielectric layer 120. The opening are lined with the barrier layer 122. The barrier layer 122 may be formed using a process such as chemical vapor deposition (CVD), physical vapor deposition (PVD), plasma enhanced CVD (PECVD), plasma enhanced physical vapor deposition (PEPVD), atomic layer deposition (ALD), combinations of these, or the like. The barrier layer may comprise tantalum nitride, although other materials, such as tantalum, titanium, titanium nitride, combinations of these, and the like may alternatively be used.

A conductive material 124 is deposited within the openings, and on the barrier layer 122. The conductive material 124 may be deposited by, for example, ALD, CVD, PVD, electrochemical plating, electroless plating, sputtering, some other deposition process, or a combination of the foregoing. In various embodiments, the conductive material 124 may be conductive and may be or include tungsten (W), copper (Cu), titanium (Ti), titanium nitride (TiN), tantalum (Ta), tantalum nitride (TaN), aluminum (Al), aluminum titanium (AlTi), some other conductive material, or a combination of the foregoing. A planarization process may be performed to remove excess of the conductive material 124. A second conductive vias 126 are formed by first portions 124a of the conductive material 124 and the barrier layer 122. An interconnect wiring 128 is formed by a second portion 124b of the conductive material 124 and the barrier layer 122. The interconnect wiring 128 may be further electrical connected to an external bonding structure (e.g., a solder bump, a micro-bump, or the like) (not shown). The capacitors 118 are electrical connected to the external bonding structure through the interconnect wiring 128 and the first conductive vias 110. The number of the first portions 124a of the conductive material 124 is merely described for illustration, and the present disclosure is not limited thereto.

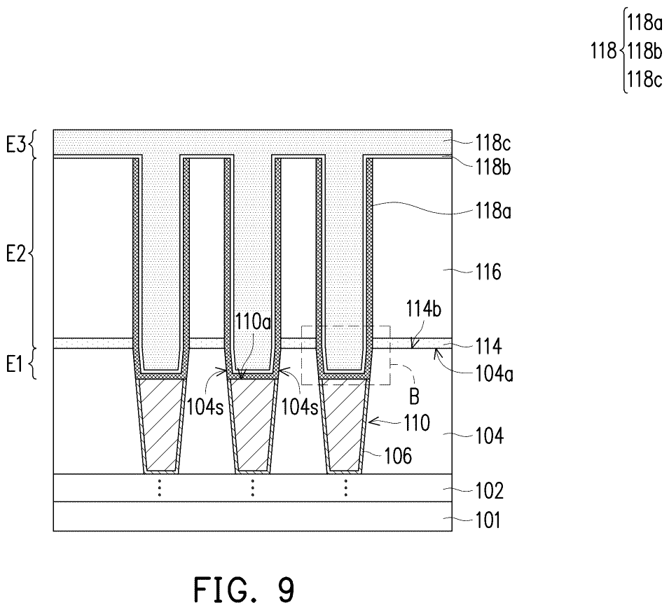

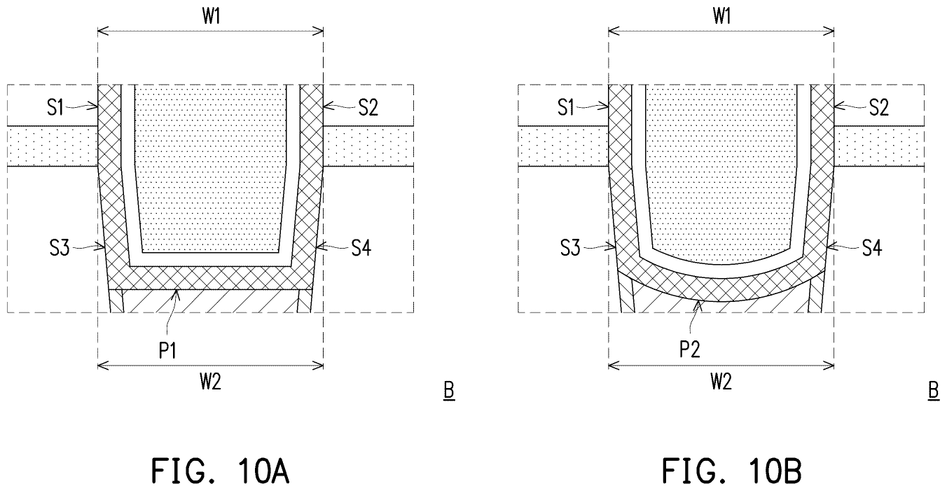

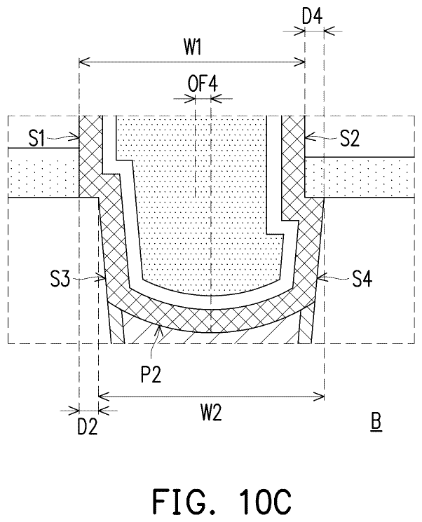

FIG. 9 to FIG. 10C illustrate the cross-sectional views of intermediate stages in the formation of a MIM device in accordance with some embodiments.

Referring to FIGS. 9 and 10A, unless further description as follows, the definition of the reference symbols and labeled representations are the same as FIGS. 6 and 7A respectively, and will not be repeated herein. FIG. 10A is an enlarge view of a portion B of FIG. 9. In FIG. 10A, the top surface 110a of the first conductive via 110 comprises a substantial planar surface P1. A maximum width W2 of the first portion E1 substantially equals to a minimum width W1 of the second portion E2, since a maximum width of the recess O2 substantially equals to a minimum width of the trench O1.

Referring to FIG. 10B, the difference of FIG. 10B and FIG. 10A is that FIG. 10B shows the top surface 110a of the first conductive via 110 comprising a curved and concave surface P2.

Referring to FIG. 10C, unless further description as follows, the definition of the reference symbols and labeled representations are the same as FIG. 10B, and will not be repeated herein.

A first central line of the first portion E1 laterally offsets from a second central line of the second portion E2. An offset distance OF4 is defined by the first central line of the first portion E1 and the second central line of the second portion E2. In some embodiments, a first lateral offset D2 is between a first sidewall S1 of the second portion E2 of the capacitor 118 and a first sidewall S3 of the first portion E1 of the capacitor 118. In some embodiments, a third lateral offset D4 is between a second sidewall S2 of the second portion E2 of the capacitor 118 and a second sidewall S4 of the first portion E1 of the capacitor 118. In some embodiments, the first lateral offset D2 substantially equals to the third lateral offset D4. In some embodiments, a sum of the maximum width W2 of the first portion E1 and the first lateral offset D2 substantially equals to the minimum width W1 of the second portion E2 and the third lateral offset D4. In some embodiments, the first lateral offset D2 substantially equals to the offset distance OF4. In some embodiments, the third lateral offset D4 substantially equals to the offset distance OF4.

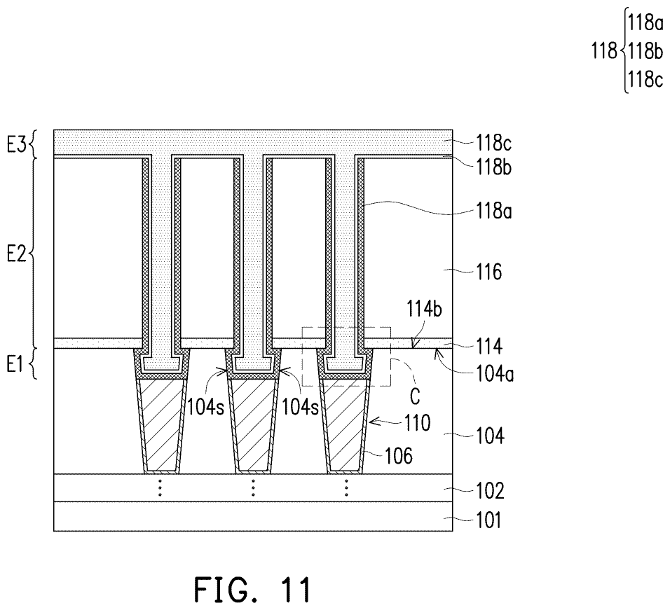

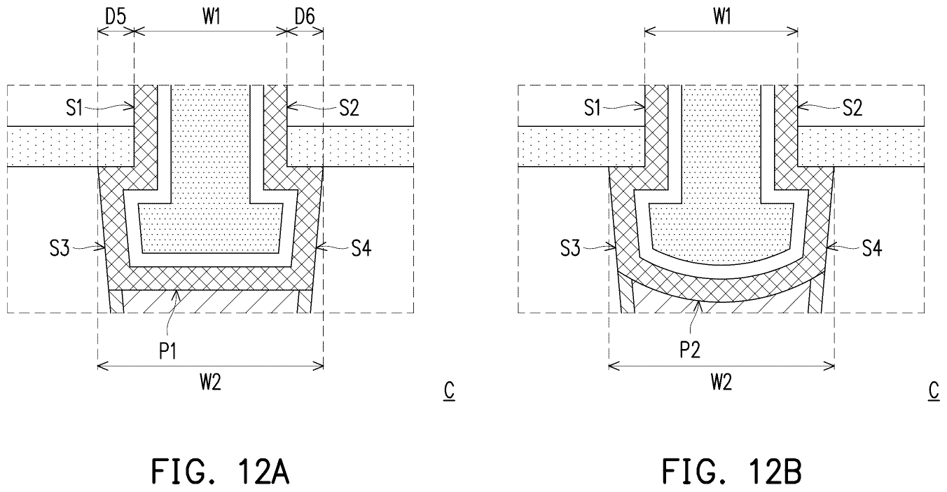

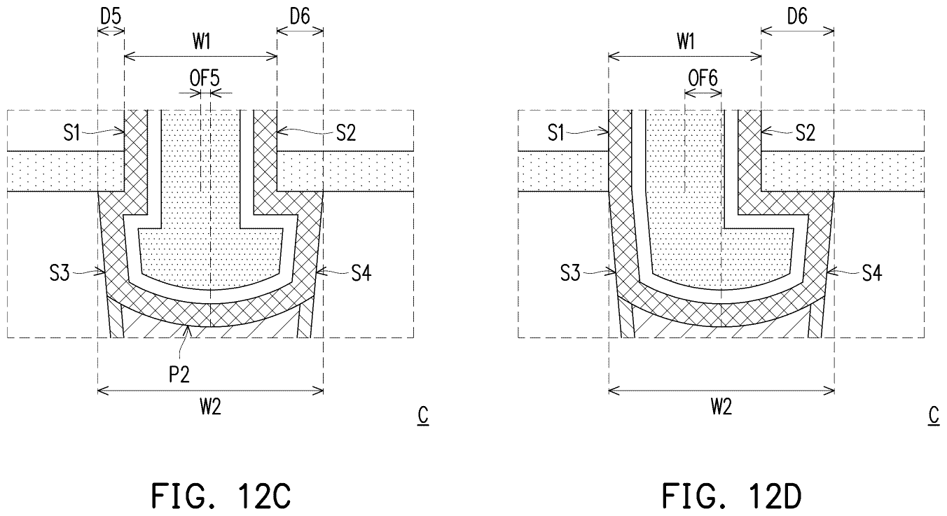

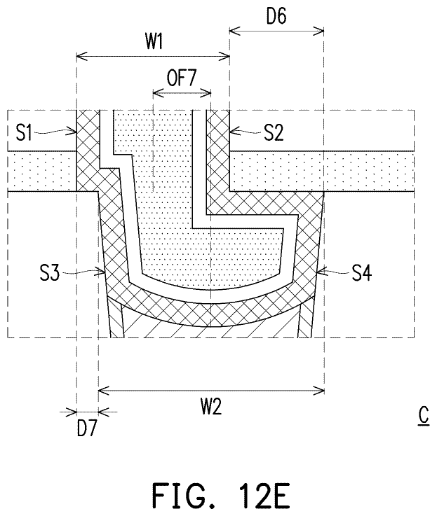

Referring to FIGS. 11 and 12A, unless further description as follows, the definition of the reference symbols and labeled representations are the same as FIGS. 6 and 7A respectively, and will not be repeated herein. FIG. 12A is an enlarge view of a portion C of FIG. 11. In FIG. 12A, the top surface 110a of the first conductive via 110 comprises a substantial planar surface P1. A maximum width W2 of the first portion E1 is larger than a minimum width W1 of the second portion E2, since a maximum width of the recess O2 larger than a minimum width of the trench O1.

In some embodiments, a fourth lateral offset D5 is between a first sidewall S1 of the second portion E2 of the capacitor 118 and a first sidewall S3 of the first portion E1 of the capacitor 118. In some embodiments, a fifth lateral offset D6 is between a second sidewall S2 of the second portion E2 of the capacitor 118 and a second sidewall S4 of the first portion E1 of the capacitor 118. In some embodiments, the fourth lateral offset D5 substantially equals to the fifth lateral offset D6. In some embodiments, a sum of the minimum width W1 of the second portion E2, the fourth lateral offset D5 and the fifth lateral offset D6 substantially equals to the maximum width W2 of the first portion E1.

Referring to FIG. 12B, the difference of FIG. 12B and FIG. 12A is that FIG. 12B shows the top surface 110a of the first conductive via 110 comprising a curved and concave surface P2.

Referring to FIG. 12C, unless further description as follows, the definition of the reference symbols and labeled representations are the same as FIG. 12B, and will not be repeated herein.

A first central line of the first portion E1 laterally offsets from a second central line of the second portion E2. An offset distance OF5 is defined by the first central line of the first portion E1 and the second central line of the second portion E2. In some embodiments, the fourth lateral offset D5 is different from the fifth lateral offset D6. In some embodiments, the fourth lateral offset D5 may be larger than or less than and the fifth lateral offset D6. In some embodiments, an absolute value of half of difference of the fourth lateral offset D5 and the fifth lateral offset D6 substantially equals to the offset distance OF5.

Referring to FIG. 12D, unless further description as follows, the definition of the reference symbols and labeled representations are the same as FIG. 12C, and will not be repeated herein.

An offset distance OF6 is defined by the first central line of the first portion E1 and the second central line of the second portion E2. In some embodiments, the first sidewall S1 of the second portion E2 is continuous and levelled with the first sidewall S3 of the first portion E1. In some embodiments, half of the fifth lateral offset D6 substantially equals to the offset distance OF6. In some embodiments, a sum of the maximum width W2 of the first portion E1 substantially equals to the minimum width W1 of the second portion E2 and the fifth lateral offset D6. The offset distance OF6 is larger than the offset distance OF5.

Referring to FIG. 12E, unless further description as follows, the definition of the reference symbols and labeled representations are the same as FIG. 12C, and will not be repeated herein.

An offset distance OF7 is defined by the first central line of the first portion E1 and the second central line of the second portion E2. In some embodiments, a sixth lateral offset D7 is between the first sidewall S1 of the second portion E2 of the capacitor 118 and the first sidewall S3 of the first portion E1 of the capacitor 118. In some embodiments, the fifth lateral offset D6 is different from the sixth lateral offset D7. In some embodiments, the fifth lateral offset D6 may be larger than the sixth lateral offset D7. In some embodiments, half of sum of the fifth lateral offset D6 and the sixth lateral offset D7 substantially equals to the offset distance OF7. In some embodiments, a sum of the maximum width W2 of the first portion E1 and the sixth lateral offset D7 substantially equals to a sum of the minimum width W1 of the second portion E2 and the fifth lateral offset D6. The offset distance OF7 is larger than the offset distance OF6.

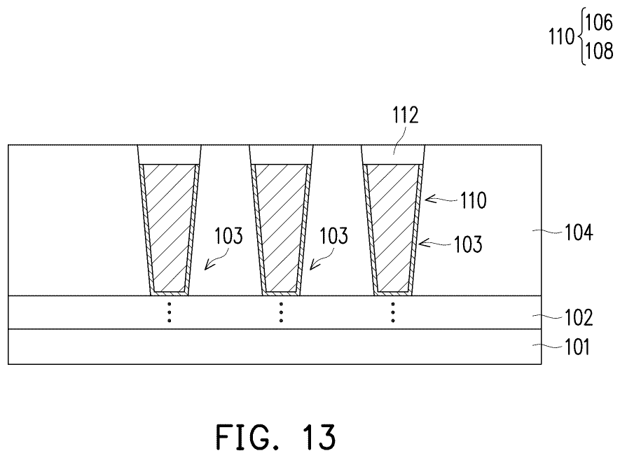

FIG. 13 to FIG. 17 illustrate the cross-sectional views of intermediate stages in the formation of a MIM device in accordance with some embodiments.

Referring to FIG. 13, FIG. 13 is the same as FIG. 2. The definition of the reference symbols and labeled representations of FIG. 13 are the same as FIG. 2, and will not be repeated herein.

Referring to FIG. 14, metal oxides 112 are removed by a wet etching process to form recesses O3. The recesses O3 reveal top surfaces 110a of the first conductive vias 110 and the sidewalls 104s of the via holes 103 of the first dielectric layer 104. In some embodiments, the metal oxides 112 are removed after the recesses O3 are formed. In some embodiments, the first conductive vias 110 are partially removed until the recesses O3 are formed above the first conductive vias 110. The recesses O3 may be achieved through a wet etching process using an etchant that is more selective to the material of the metal oxides 112 than the material of the first dielectric layer 104. The wet etching process may be performed using an etchant such as HF. The wet etching process may be performed using a dip process, a spray process, a spin-on process, or the like, and may be performed using any suitable process temperatures. Depths D1 of the recesses O3 are defined by the top surfaces 110a of the first conductive vias 110 between the top surfaces 104a of the first dielectric layer 104. The depths D1 of the recesses O3 are greater than about 10 Å. The number of the recesses O3 is merely described for illustration, and the present disclosure is not limited thereto.

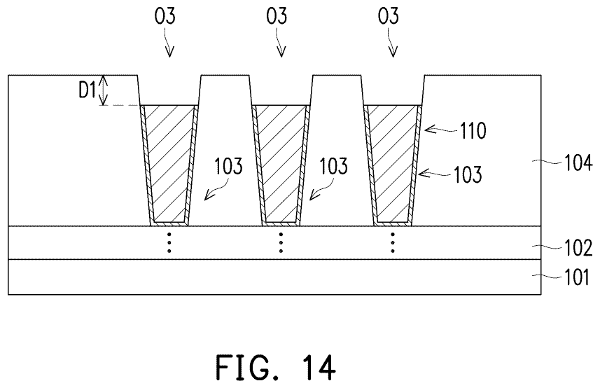

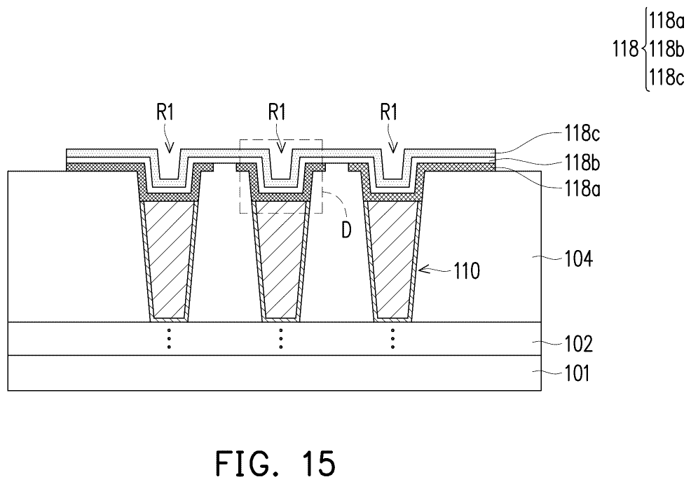

Referring to FIG. 15, unless further description as follows, the definition of the reference symbols and labeled representations are the same as FIG. 6, and will not be repeated herein.

Capacitors 118 are conformally formed in the recesses O3 of the first dielectric layer 104. In some embodiments, the capacitors 118 are patterned by a photolithography process followed by an etch process, and a photomask is used in the photolithography process. The capacitors 118 are partially embedded in the first dielectric layer 104 and is partially disposed above the first dielectric layer 104. The capacitors 118 are disposed on and electrically connected to the first conductive vias 110. The capacitors 118 protrude into the first dielectric layer 104 to electrically connect the first conductive vias 110. Contact interfaces between the first conductive vias 110 and the capacitors 118 are lower than interfaces between the top surfaces 104a of the first dielectric layer 104 and the capacitors 118. The top surfaces 110a of the first conductive vias 110 are lower than the top surfaces 104a of the first dielectric layer 104.

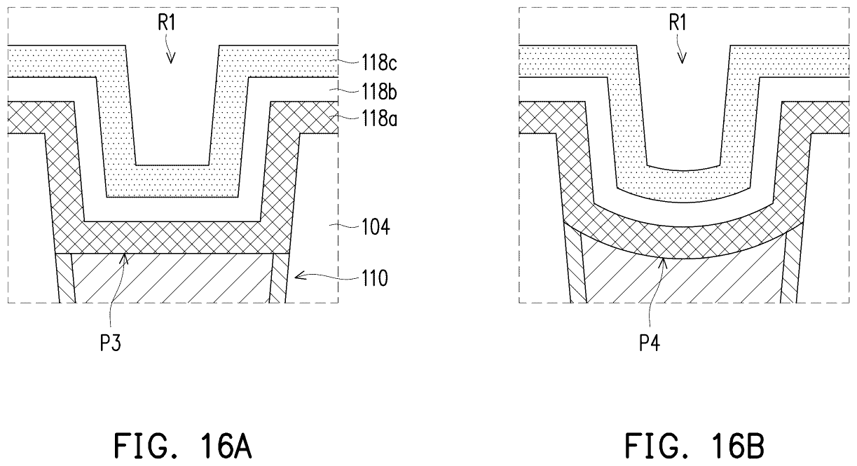

FIG. 16A is an enlarge view of a portion D of FIG. 15. Referring to FIG. 16A, the top surface 110a of the first conductive via 110 comprises a substantial planar surface P3. The capacitor 118 is physically in contact with the top surface 104a of the first dielectric layer 104. The capacitor 118 lands on the top surface 104a of the first dielectric layer 104. In some embodiments, a recess RI is above and within the second capacitor electrode layer 118c of the capacitor 118.

Referring to FIG. 16B, the difference of FIG. 16B and FIG. 16A is that FIG. 16B shows the top surface 110a of the first conductive via 110 comprising a curved and concave surface P4.

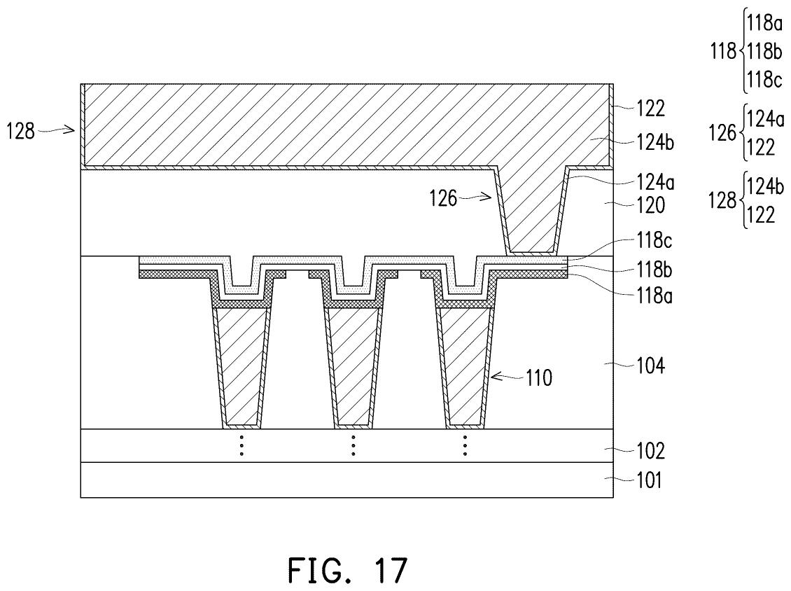

Referring to FIG. 17, forming a second conductive vias 126 are formed on the capacitors 118. The second conductive vias 126 are disposed on and electrically connected to the second capacitor electrode layer 118c of the capacitors 118.

In some embodiments, the third dielectric layer 120, the second conductive vias 126 and the interconnect wiring 128 may be formed by the same processes and the same materials as FIG. 8, and will not be repeated herein.

A capacitor structure and a method for fabricating the capacitor are provided. An oxide layer between a bottom electrode and the capacitor is removed in the fabrication method for forming the capacitor structure with low resistance, thereby increasing the capacitive coupling area of the capacitor structure and improving the quality of the capacitor structure. Accordingly, the electrical performance of the capacitor structure can be improved.

In accordance with some embodiments of the present disclosure, a structure is provided. In some embodiments, the structure comprises a first dielectric layer, a first conductive via embedded in the first dielectric layer, an etch stop layer disposed on the first dielectric layer, a second dielectric layer disposed on the etch stop layer, and a capacitor embedded in the first dielectric layer, the etch stop layer and the second dielectric layer. The capacitor is disposed on and electrically connected to the first conductive via. A contact interface between the first conductive via and the capacitor is lower than an interface between the first dielectric layer and the etch stop layer. In some embodiments, a top surface of the first dielectric layer interfaces and is in contact with a bottom surface of the etch stop layer, and a top surface of the first conductive via is lower than the top surface of the first dielectric layer. In some embodiments, a top surface of the first conductive via comprises a substantial planar surface. In some embodiments, a top surface of the first conductive via comprises a curved and concave surface. In some embodiments, the capacitor comprises a first portion and a second portion, the first portion protrudes into the first dielectric layer, and the second portion is embedded in the etch stop layer and the second dielectric layer. In some embodiments, the first portion of the capacitor is spaced apart from the second dielectric layer by the etch stop layer. In some embodiments, a maximum width of the first portion is less than or greater than a minimum width of the second portion. In some embodiments, a maximum width of the first portion substantially equals to a minimum width of the second portion. In some embodiments, the capacitor comprises a first capacitor electrode layer disposed on and electrically connected to the first conductive via, a capacitor dielectric layer disposed on the first capacitor electrode layer, and a second capacitor electrode layer disposed on the capacitor dielectric layer. In some embodiments, the structure further comprises a second conductive via disposed on and electrically connected to the second capacitor electrode layer.

In accordance with some embodiments of the present disclosure, a structure is provided. In some embodiments, the structure comprises a first dielectric layer, a first conductive via embedded in the first dielectric layer, a second dielectric layer disposed over the first dielectric layer, and a capacitor penetrating through the second dielectric layer and protruding into the first dielectric layer to electrically connect the first conductive via. The capacitor comprises a first portion and a second portion. The first portion is embedded in the first dielectric layer. The second portion lands on the first portion and is embedded in the second dielectric layer. A first central line of the first portion laterally offsets from a second central line of the second portion. In some embodiments, a contact interface between the first conductive via and the capacitor is lower than an interface between the first dielectric layer and the etch stop layer. In some embodiments, the structure further comprises an etch stop layer disposed between the first dielectric layer and the second dielectric layer. The second portion penetrates through the etch stop layer and lands on the first portion. In some embodiments, the second portion is in contact with a top surface of the first dielectric layer. In some embodiments, the first conductive via comprises a barrier layer and a conductive material disposed on the barrier layer. The conductive material is spaced apart from the first dielectric layer by the barrier layer. Top ends of the barrier layer are in contact with the capacitor. A first level height where the top ends of the barrier layer are located is lower than a second level height wherein a bottom surface of the etch stop layer is located.

In accordance with some embodiments of the present disclosure, a method for fabricating a capacitor is provided. In some embodiments, the method comprises forming a first conductive via in a first dielectric layer; forming a second dielectric layer over the first dielectric layer; forming a trench in the second dielectric layer to reveal a top surface of the first conductive via; partially removing the first conductive via until a recess is formed above the first conductive via; and forming a capacitor in the trench of the second dielectric layer and the recess. In some embodiments, the method further comprises forming a second conductive via on the capacitor. In some embodiments, the method further comprises forming an etch stop layer on the first dielectric layer before forming the second dielectric layer over the first dielectric layer, wherein the trench is formed in the etch stop layer and the second dielectric layer. In some embodiments, a metal oxide generates after forming the first conductive via in the first dielectric layer and before forming the second dielectric layer over the first dielectric layer, and the metal oxide is removed after the recess is formed. In some embodiments, partially removing the first conductive via comprises performing a wet etching process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a first dielectric layer;
a first conductive via embedded in the first dielectric layer;
an etch stop layer disposed on the first dielectric layer;
a second dielectric layer disposed on the etch stop layer; and
a capacitor embedded in the first dielectric layer, the etch stop layer and the second dielectric layer, the capacitor being disposed on and electrically connected to the first conductive via, wherein a contact interface between the first conductive via and the capacitor is lower than an interface between the first dielectric layer and the etch stop layer.

2. The structure of claim 1, wherein a top surface of the first dielectric layer interfaces and is in contact with a bottom surface of the etch stop layer, and a top surface of the first conductive via is lower than the top surface of the first dielectric layer.

3. The structure of claim 2, wherein a top surface of the first conductive via comprises a substantial planar surface.

4. The structure of claim 2, wherein a top surface of the first conductive via comprises a curved and concave surface.

5. The structure of claim 1, wherein the capacitor comprises a first portion and a second portion, the first portion protrudes into the first dielectric layer, and the second portion is embedded in the etch stop layer and the second dielectric layer.

6. The structure of claim 5, wherein the first portion of the capacitor is spaced apart from the second dielectric layer by the etch stop layer.

7. The structure of claim 5, wherein a maximum width of the first portion is less than or greater than a minimum width of the second portion.

8. The structure of claim 5, wherein a maximum width of the first portion substantially equals to a minimum width of the second portion.

9. The structure of claim 1, wherein the capacitor comprises:
a first capacitor electrode layer disposed on and electrically connected to the first conductive via;
a capacitor dielectric layer disposed on the first capacitor electrode layer; and
a second capacitor electrode layer disposed on the capacitor dielectric layer.

10. The structure of claim 9 further comprising a second conductive via disposed on and electrically connected to the second capacitor electrode layer.

11. A structure, comprising:
a first dielectric layer;
a first conductive via embedded in the first dielectric layer;
a second dielectric layer disposed over the first dielectric layer; and
a capacitor penetrating through the second dielectric layer and protruding into the first dielectric layer to electrically connect the first conductive via, wherein the capacitor comprises a first portion and a second portion, the first portion is embedded in the first dielectric layer, the second portion lands on the first portion and is embedded in the second dielectric layer, and a first central line of the first portion laterally offsets from a second central line of the second portion.

12. The structure of claim 11, wherein a contact interface between the first conductive via and the capacitor is lower than an interface between the first dielectric layer and the etch stop layer.

13. The structure of claim 11 further comprising:
an etch stop layer disposed between the first dielectric layer and the second dielectric layer, wherein the second portion penetrates through the etch stop layer and lands on the first portion.

14. The structure of claim 13, wherein the second portion is in contact with a top surface of the first dielectric layer.

15. The structure of claim 13, wherein the first conductive via comprises a barrier layer and a conductive material disposed on the barrier layer, the conductive material is spaced apart from the first dielectric layer by the barrier layer, top ends of the barrier layer are in contact with the capacitor, and a first level height where the top ends of the barrier layer are located is lower than a second level height wherein a bottom surface of the etch stop layer is located.

16. A method, comprising:
forming a first conductive via in a first dielectric layer;
forming a second dielectric layer over the first dielectric layer;
forming a trench in the second dielectric layer to reveal a top surface of the first conductive via;
partially removing the first conductive via until a recess is formed above the first conductive via; and
forming a capacitor in the trench of the second dielectric layer and the recess.

17. The method of claim 16 further comprising forming a second conductive via on the capacitor.

18. The method of claim 16 further comprising:
forming an etch stop layer on the first dielectric layer before forming the second dielectric layer over the first dielectric layer, wherein the trench is formed in the etch stop layer and the second dielectric layer.

19. The method of claim 16, wherein
a metal oxide generates after forming the first conductive via in the first dielectric layer and before forming the second dielectric layer over the first dielectric layer, and
the metal oxide is removed after the recess is formed.

20. The method of claim 16, wherein partially removing the first conductive via comprises performing a wet etching process.
